(19) United States
(12) Patent Application Publication
(10) Pub. No.: US 2026/0066705 A1
(43) Pub. Date: Mar. 5, 2026

(54) WIRELESS MICROPHONE CHARGER

(71) Applicant: Sound Devices LLC, Reedsburg, WI (US)

(72) Inventors: Matthew G. Anderson, Madison, WI (US); Jason McDonald, Madison, WI (US); Steven David Carr, Madison, WI (US)

(73) Assignee: Sound Devices LLC, Reedsburg, WI (US)

(21) Appl. No.: 19/311,558

(22) Filed: Aug. 27, 2025

Related U.S. Application Data
(60) Provisional application No. 63/688,022, filed on Aug. 28, 2024.

(51) Int. Cl. H02J 50/10; H02J 50/00; H02J 50/40; H02J 50/90; H04R 1/08; H05K 7/20

(52) U.S. Cl. CPC H02J 50/10; H02J 50/005; H02J 50/402; H02J 50/90; H04R 1/083; H05K 7/20145; H04R 2420/07

(57) ABSTRACT

A handheld wireless microphone has a receiving coil used for induction charging by placing the microphone vertically into a charging holster in a charging station. The receiving coil is located concentrically with the charging coil wound around the charging holster and provides effective magnetic coupling. Ferrite plates are used to enhance inductive coupling and minimize interference from metal components in the microphone. Due to the symmetry of the charging holster and transmitting coil, the user need not concern themselves with the rotary orientation of the microphone when placing it vertically into the holster.

### CROSS-REFERENCE TO RELATED APPLICATION

The present application claims priority of U.S. Provisional Patent Ser. No. 63/688,022, filed Aug. 28, 2024, the content of which is incorporated herein by reference in its entirety.

### FIELD OF THE INVENTION

The invention relates to a wireless charging system designed to improve flexibility and portability for wireless microphones. More particularly, the invention pertains to a system where a user may simply place a handheld wireless microphone in a holster of an induction charging station that does not require physical electrical contact between the microphone and charging station. The configuration of inductive coils in the charging station and the microphone body optimizes energy transfer and improves the reliability for the system. It furthermore reduces concerns regarding how the microphone should be positioned when placed in the charging station holster.

### BACKGROUND OF THE INVENTION

Wireless chargers provide means to transfer electrical energy (power) from a charging station to a device that can store received energy in rechargeable batteries for later use. In most cases, energy may be transferred via a time-varying magnetic field that is coupled between a charging station and the device being charged. If the time-varying magnetic field is directed through a receiving coil in the device, a voltage will be induced around this coil allowing for extraction of energy supplied by the magnetic field. From a user perspective, advantages of wireless charging include the convenience of having no physical electrical contacts that need to be connected (or aligned for connection) and sometimes wireless charging allows for a greater degree of freedom in the placement for an electrical device to be charged in relation to the charging station when charging is desired.

Wireless chargers known in the art often utilize an interface between two flat surfaces that oppose one another. In this mode, a charging station (charging) coil may be mounted below a first surface, where a receiving coil is placed above in a second opposing surface, which is often part of the construction for the device to be charged. A well-known example of this method is often used for charging commercially available cell phones, where an angled flat support surface is provided by a charging station, whereby a user may lean a cell phone against it when charging is desired. Since this method is based on the proximity of two flat surfaces, where a transmitting and receiving coil exist on either side, a pathway necessarily exists along the plane between these surfaces where portions of the magnetic flux generated by the charging station coil may exit and wrap around outside the charging coil without looping through the receiving coil. For some prior-art embodiments, this may reduce the degree of magnetic coupling between the charging coil and receiving coil, affecting the overall efficiency for the charging system.

### SUMMARY OF THE INVENTION

The invention pertains to a wireless microphone charging system including a handheld microphone with a rechargeable battery and a wireless charging station. The handheld microphone has an elongated microphone body. A receiving coil is wound and located inside the sleeve of the microphone body and extends circumferentially around a section of the elongated microphone body, preferably above the radome for an antenna at the base of the elongated microphone body. The wireless charging station has a holster with a receptacle for receiving the microphone body. In the preferred embodiment, the receptacle has a functionally cylindrical shape and an opening through which the microphone body is set into the receptacle. A charging coil is wound around the cylindrical receptacle wall. The receptacle is configured to hold the microphone body in a vertical position when fully seated such that the receiving coil on the microphone body resides annularly within the charging coil in the holster, preferably concentrically or substantially concentrically. With this configuration, the receiving coil magnetically couples efficiently to the charging coil when charging to transfer power from the charging coil to the receiving coil via induction.

One advantage of the invention is that the charging station holster receives the handheld wireless microphone (to be charged) into the opening of the holster without the need to align any connectors requiring physical contact. Charging of the microphone is fully automated so the user need not concern themselves with the state (level of charge remaining in the battery) that rechargeable batteries are in prior to placing the microphone into the holster.

Another advantage is that holster may be constructed in such a manner that gravity holds the microphone in a fully seated position to provide proper coupling between the charging coil and the microphone (receiving) coil. Also, symmetry for magnetic coupling about the axis of the microphone and charging station holster receptacle removes the need for the user to be concerned about the rotational (angular) orientation of the microphone (with respect to its axis) when placing it into the holster receptacle.

In one exemplary embodiment, the wireless microphone has an internal metal frame and a conical antenna as disclosed in U.S. Ser. No. 19/032,311, entitled “Wireless Microphone Dipole RF Antenna,” filed on Jan. 20, 2025, published as Pub. No. 2025/0239777 A1, and assigned to the assignee of the present application. It is important with this embodiment, as well as with other embodiments, that interference of the magnetic field generated by the charging coil on the charging station by metal structures in the microphone be minimized, since interference can lead to inefficiency and excess heat generation. In this regard, the relative positioning of the magnetic field generated by the charging coil with respect to both the receiving coil on the microphone and other metal microphone components is selected desirably to minimize such interference. In addition, ferrite plates can be used to redirect the magnetic flux through the ferrite plates and away from potentially interfering metal components. Non-conductive materials other than ferrite with high magnetic permeability may also be suitable for this purpose. In the preferred embodiment implementing the antenna in incorporated U.S. Ser. No. 19/032,311, a annular ferrite plate is located adjacent the inside surface of the receiving coil, and a flat ferrite plate is placed above the receiving coil and below the main metal frame in the microphone body, see FIGS. 12 and 13.

The charging station desirably includes a cooling fan to blow cooling air over the charging coils and around the wireless microphones. In one exemplary embodiment, the charging station is adapted with two charging holsters to charge two wireless microphones, and the cooling air fan is used to cool the charging coils for each of the two charging holsters. It is possible and often desirable to connect two or more charging stations together. This has the advantage of having to provide only one power cord to the connected charging stations, and it also enables data communication between the charging stations so that charging can be optimized across the charging holsters in which a microphone has been set. In the preferred embodiment, charging power is supplied and managed according to the USB-PD fast charging protocol.

Other embodiments and features of the invention may be apparent to those skilled in the art upon review of the drawings and the following description thereof.

### BRIEF DESCRIPTION OF THE DRAWINGS

FIGS. 1A and 1B illustrate a first embodiment of the invention and show a handheld wireless microphone body in relation to a charging station. In FIG. 1A, the microphone is located above the holster receptacle (opening) of the charging station. In contrast, in FIG. 1B, the lower part of the microphone body has been inserted into the holster receptacle of the charging station.

FIG. 2 is a cutaway view of the first embodiment illustrating the internal construction, including location and orientation for both the charging coil in the charging station and receiving coil of the microphone body. Notably the receiving coil 105 in the microphone body is located concentrically within the charging coil 205 mounted in the charging station.

FIG. 3 is a top view of a cross section taken through the charging station with the microphone inserted into the holster receptacle (as in FIG. 2) at a level such that it crosses through the charging and receiving coils.

FIG. 4 is a perspective view illustrating a second embodiment of the invention in which a pair of wireless microphones are located in a charging station having two holster receptacles.

FIG. 5 is a perspective view of the rear side of the charging station in the second embodiment of the invention showing the two microphones removed from the holster receptacle.

FIG. 6 is a rear perspective view of the second embodiment showing the microphones located in the holster receptacles of the charging station, also showing the housing in dashed lines to illustrate internal components of the charging station.

FIG. 7 is a front perspective view of the second embodiment with the housing of the charging station removed.

FIG. 8 is a rear elevational view of the second embodiment of the invention.

FIG. 9 is a schematic view illustrating cooling air flow in the second embodiment of the invention.

FIG. 10 is a cross-sectional view taken along line 10-10 in FIG. 8.

FIG. 11 is a view illustrating various internal components of the internal metal frame and antenna of the wireless microphone disclosed in the incorporated US. Ser. No. 19/032,311, entitled “Wireless Microphone Dipole RF Antenna,” filed on Jan. 2025 and assigned to the assignee of the present application. FIG. 11 also illustrates the relative positioning of the charging coil on the charging station with respect to the illustrated microphone components.

FIG. 12 is a sectional view through FIG. 11 and illustrates the preferred location of ferrite plates to redirect magnetic energy away from metal components.

FIG. 13 is a detailed view of the lower part of FIG. 12

FIG. 14 describes electrical and magnetic energy flow when the invention is operating to charge the microphone battery or batteries.

### DETAILED DESCRIPTION OF THE INVENTION

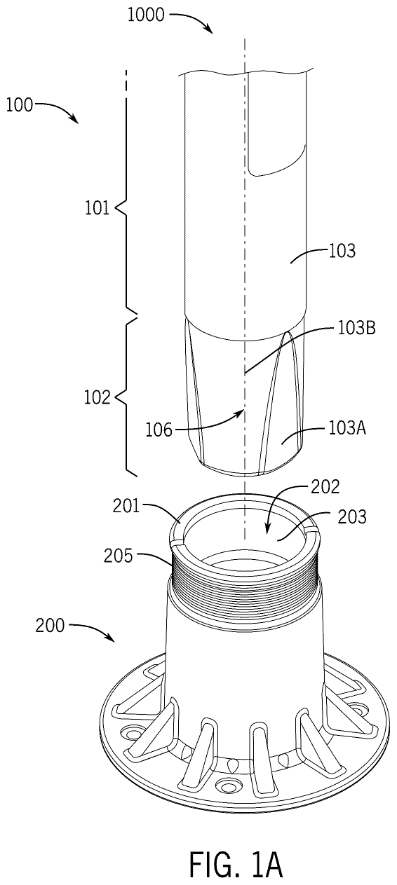

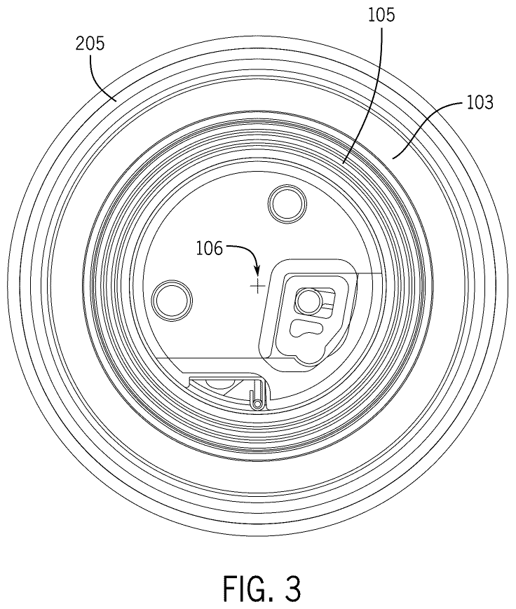

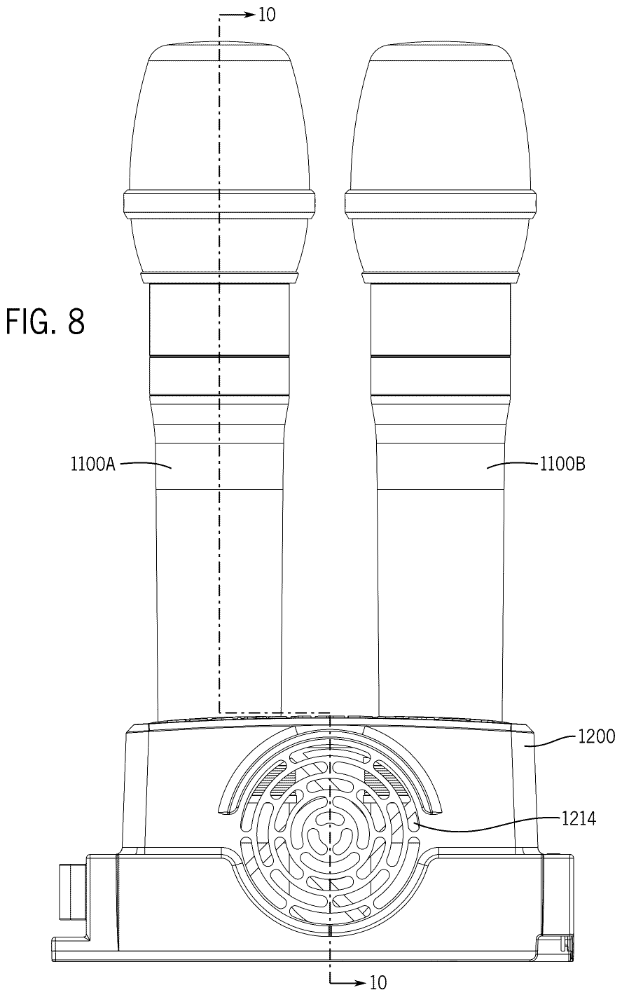

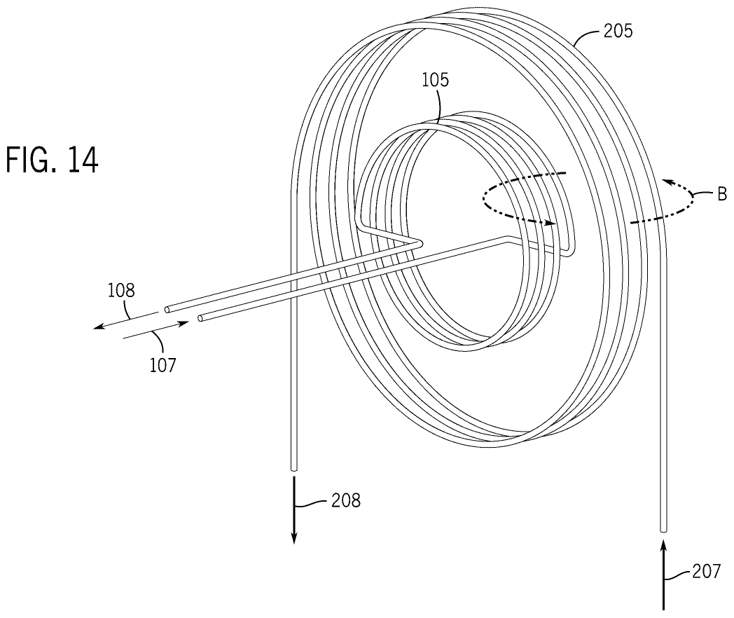

FIGS. 1A, 1B, 2 and 3 are directed to a first exemplary embodiment of the invention and FIGS. 4 through 13 are directed to a second exemplary embodiment of the invention. FIG. 14 describes electrical and magnetic energy flow when the invention is operating and is pertinent to both the first and the second described embodiments. The drawings illustrate two different, exemplary embodiments of the invention, although it should be understood that the invention can be implemented in other forms or embodiments.

Referring to FIGS. 1A and 1B, reference number 1000 refers to a complete handheld wireless microphone charging system constructed in accordance with a first embodiment of the invention. This system 1000 combines both a wireless handheld wireless microphone 100 with a wireless microphone charging station 200 that is configured to receive a compatible wireless microphone 100 into a receptacle 202 in a holster 201 for charging. As shown in FIG. 1A, the microphone 100 has a center axis 106 defined as a line extending along the lengthwise axis of the microphone 100. Due to the (circular) symmetry of both the microphone 100 and the charging station 200, this center axis 106 could be considered as applicable to either the microphone 100 or charging station 200 when the microphone 100 is fully seated in the holster 201 of the charging station 200.

In the preferred embodiments illustrated in the drawings, the microphone 100 is inserted from the top down into the holster 201. Only the lower portion of the handheld wireless microphone 100 is shown in FIGS. 1A and 1B. Specifically, the lower portion for the sleeve 103 around the microphone body 101 is attached to a radome (or antenna cover) 102. The antenna cover 102 is typically attached to the with threads to the sleeve 103, although in some microphones the antenna cover is an integral part of the sleeve. The microphone in FIG. 1A has scallops 103A symmetrically embedded (indented) in a portion of the antenna covering 102. The scallops 103A may extend up into the main portion of the microphone sleeve 101 depending on preference. Although the presence of scallops may affect the profile for part of the surface of the antenna cover 102 (and possibly the main microphone sleeve 101), the scallops 103A are for ornamental (decorative) purposes only and serve no function with respect to how the handheld microphone 100 remains oriented after placing it into its charging station 200. Preferably, the reverse profile for the scallops 103A is not molded into the inner surface for the holster 201. If the inner surface of the holster 201 is constructed such that has a circular cross section along its length, only the landing portion 103B of the antenna cover 102 will come into direct contact with the inside surface 203 of the holster 201 when the microphone 100 is inserted into the charging station 200.

This sort of circular symmetry for the landing portion 103B of the antenna cover 102 coupled with the circular symmetry of the holster landing zone defined by the inside surface 203 of the holster 201 enables the microphone 100 to be gravitationally held in a steady vertical position (without wobbling) in the charging station holster 201 regardless of the rotary angle that the microphone is set with respect to the center axis 106. As indicated in FIG. 1B, the scallops 103A and the antenna cover 102 may be sized such that they are entirely covered by the charging station 200 when the microphone 100 is fully inserted into the holster 201 of the charging station 200.

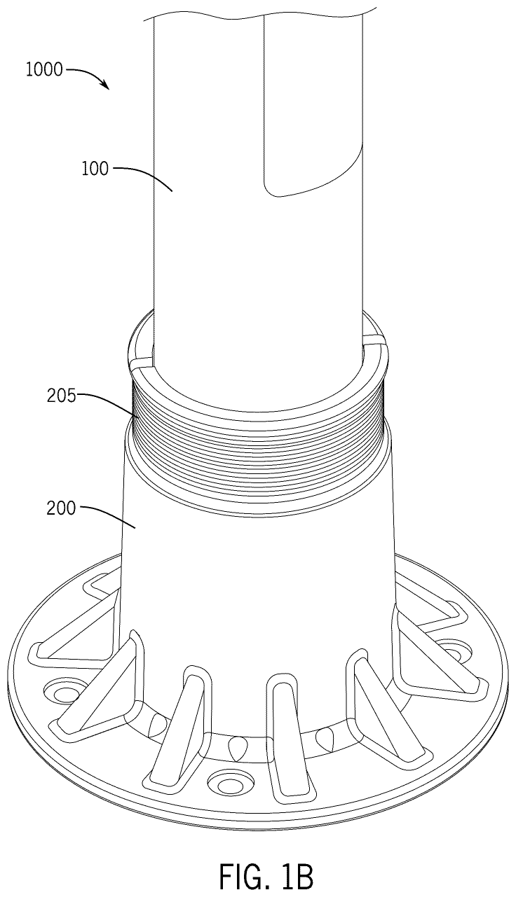

After the microphone 100 is fully inserted into the charging station 200, the charging coil 205 and receiving coil 105 (FIG. 2) are positioned concentrically such that they are magnetically coupled to facilitate the transfer of (magnetic) energy between them.

FIG. 2 illustrates the microphone 100 fully seated in the holster 201 of the charging station 200 with a vertical angular section cutaway to illustrate the internal configuration and placement of elements, in particular the receiving coil 105 on the microphone 100 and charging coil 205 on the charging station 200. In this view, the cutaway (removed) section has a volume with a V-shaped cross section that runs along the center axis 106 of the microphone 100 and holster 201 of the charging station 200. As can be seen, the size and position of the two coils 105, 205 are selected so that the coils 105, 205 are concentric and each have an axis coinciding substantially along the center axis 106 of the microphone 100. This configuration provides an important advantage. Generally, the magnetic field produced by wire coil consists of looped field lines that propagate near the axis through the interior of the coil and wrap back the around outside of it. Consider a cylindrical volume, V_{ch} to be the region enclosed by the charging coil 205, terminated on either end by the plane spanned by the uppermost and lowermost (with respect to the center axis 106) wire loops in the charging coil 205. Desirably, the receiving coil 105 is placed such that it is entirely contained within this cylindrical volume V_{ch}. The receiving coil 105 is also set so that it is concentric or nearly concentric with the charging coil 205. In other words, all field lines that propagate (loop) through the interior of the receiving coil 105 must also propagate (loop) through the interior of the charging coil 205—leading to an improved (optimized) level of magnetic coupling between the coils 105, 205.

Referring to FIG. 14, a receiving coil 105 is shown to be concentrically positioned within a charging coil 205. When the charging station 200 is plugged in and activated, the electronics in the charging station convert the power from, e.g., 120 AC or USB PD power, into high frequency alternating current. This high frequency alternating current 207, 208 flows through the charging coil 205, which generates an oscillating or changing magnetic field B around the charging coil 205. The receiving coil 105 is positioned within the changing magnetic field B (when the microphone 100 is placed in the charging station 200). According to the principle of electromagnetic induction, the changing magnetic field B induces an alternating current 107, 108 in the receiver coil 105. The induced alternating current 107, 108 is rectified into a direct current and filtered and processed to charge the battery.

Referring again to FIG. 2, a cylindrical cavity 109 located along the center axis 106 of the microphone 100 serves as a battery compartment 109. In some embodiments, it may be desirable to place the battery compartment 109 closer to the edge of the microphone sleeve 103 with a removable (clip-in) door (hatch) to allow for convenient access. A spring type electrical contact 110 may be placed at the lower end of the battery compartment 109 to contact the negative terminal for the rechargeable battery and hold it in place when installed. Preferably, a 3.7V rechargeable battery of type 18650 (lithium ion) removably inserted in the battery compartment 109 to provide power to the microphone 100 while in use. These batteries provide a convenient size and reliability, enable numerous recharge cycles, are commercial availability at low cost and typically have a capacity exceeding 2-3 thousand mAh.

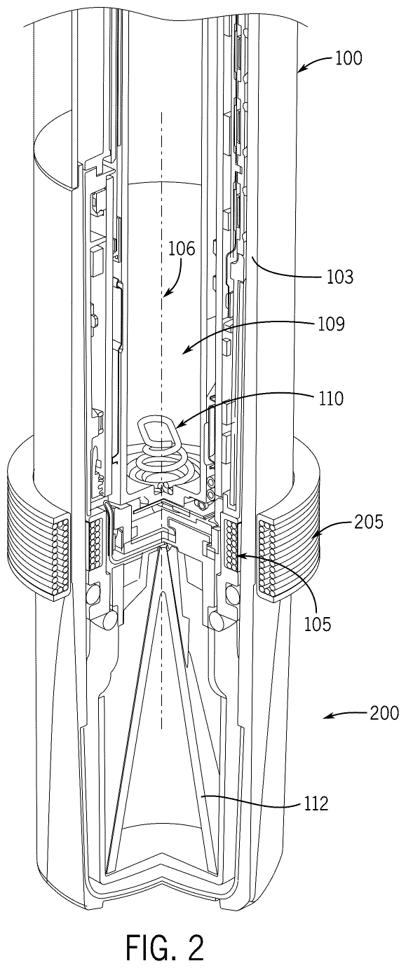

The advantageous positioning of the receiving coil 105 and charging coil 205 is further illustrated by FIG. 3, showing a horizontal cross section through the microphone 100 and charging station 200 at the elevation of the charging coil 205 and receiving 105 coil when the microphone 100 is fully inserted into the charging station holster 201. FIG. 3 also shows the charging coil 205 radially surrounding the receiving coil 105 to optimize magnetic coupling. The microphone sleeve 103 surrounds the receiving coil 105, see also FIG. 2, but is made of a plastic material that does not materially affect the magnetic field. The charging holster 201 is configured so that charging coil 205 is close to the microphone sleeve 103 when the microphone is loaded into the holster. It is also configured with the charging coil 205 and receiving coil 105 positioned to minimize interference from metal components, such as the conical antenna 112 shown in FIG. 2.

Users are generally aware that rechargeable battery life is finite. In order to minimize the risk of a wireless microphone running out of power while in use, users may often elect to keep the microphone in a fully charged state by placing it in a charging station whenever not in use. As such, when a user places a handheld wireless microphone 100 into a charging station 200, recharging of the microphone 100 does not always begin from a fully discharged state. There is also a risk that users who are not familiar with such devices may inadvertently) place an object other than a compatible wireless microphone 100 into the holster 201 of a charging station 200. In these cases (especially for metal objects) applying a full amplitude modulating magnetic field may result in heating the object and create a safety hazard. To address these issues, the Wireless Power Consortium (WPC) has developed a progressive set of standards that includes the “Qi” Standard intended for tightly coupled inductive chargers that has become a widely used standard. As of 2015, this standard was updated to include power levels up to 15 W with version 1.2 of the standard. In 2021, the WPC released version 1.3 (WPC/Qi 1.3) of the standard that provided improved features for foreign object detection (FOD) along with a substantial number of compliance tests (that were not tested for older versions). An advantage of this approach is premade integrated circuits (IC's) have become commercially available that can implement this standard in stand-alone operation without the need for additional processing units. For example, Infineon offers a wireless transmitter controller (part number WLC1115-68LQXQ compatible with WPC/Qi 1.3) that may be integrated into electronics on the charging station 200 and coupled with a receiver controller made by Kinetic Technologies (part number KTE7001ENAA-DA-TB) that may be integrated with electronics in the wireless handheld microphone 100 for compatibility with WPC/Qi 1.3. These parts (IC's as shipped) internally contain firmware to provide for power control that integrates all the requirements for a WPC “Qi” compliant wireless power transfer. This includes the ability to exchange information, such as sending packets from the receiver IC (microphone) to the transmitter IC (charging station) via FSK communications. The transmitter IC (charging station) is then able to provide control over the voltage, phase shift and duty cycle for the transmitter power stage (charging station) according to message packets sent by the receiver controller (microphone).

The charging station can be adapted to receive 120 VAC power, in which case the the charging station desirably has an AC to DC power converter that converts the power to a low DC voltage suitable for the transmitter Qi wireless charging controller on the charging station. Alternatively, an external converter can be used to supply the power to a low DC voltage suitable for the transmitter Qi wireless charging controller, the charging station can receive power via a USB or USB-C connection and convert the voltage if necessary for the transmitter Qi wireless charging controller. In the second embodiment of the invention described below with respect to FIGS. 4 through 13, power is provided to a USB-PD circuit, as discussed in more detail below.

The charging coil 205 is connected to the Qi wireless charging controller on the charging station. The receiver coil 205 on the microphone is connected to the receiver Qi wireless charging controller, which in turn is connected to the battery contacts thereby enabling charging of the rechargeable battery on the microphone. The receiver Qi wireless charging controller can be connected to a power supply circuit that is able to not only charge the rechargeable batteries but also provide power directly for microphone operation, if this feature is desired.

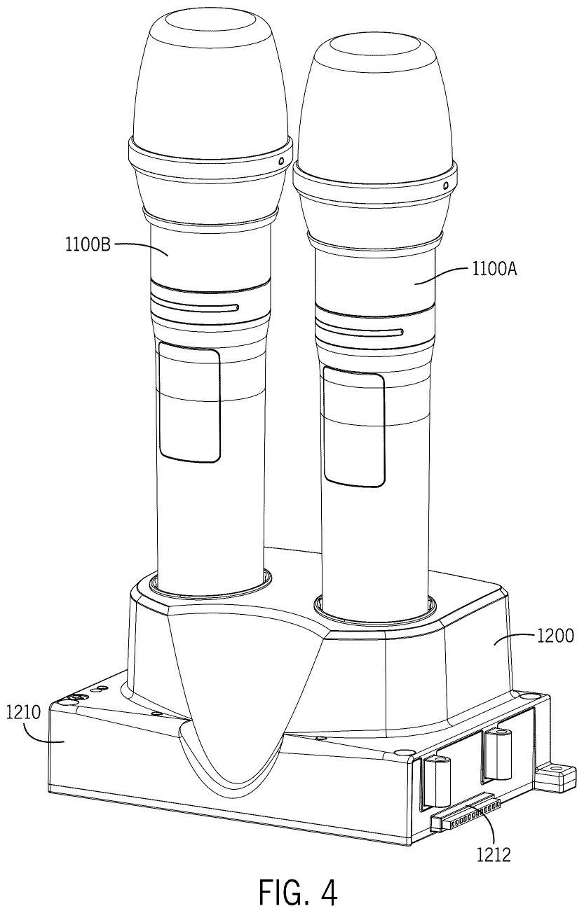

Referring now in particular to FIGS. 4 through 9, the second embodiment of the invention has a charging station 1200 with two charging holsters 1201A, 1201B, which each receive a wireless microphone 1100A, 1100B. The wireless microphones 1100A, 1100B are vertically placed in the respective charging holster 1201A, 1201B, with the antenna on the bottom and the microphone head facing upward. The charging station 1200 has a base section 1210 that holds a printed circuit board and provides mounting for a cooling fan 1216. FIG. 4 shows an electrical pin connector 1212 that is used to connect to additional charging stations 1200, for example, having the same configuration as shown in FIG. 4. FIG. 5 shows the rear of the charging station 1200 with the wireless microphones 1100A, 1100B removed from the respective charging holsters 1201A, 1201B. The housing on the charging station 1200 includes a molded grill 1214 providing air flow to the fan 1216. Each of the charging holsters 1201A, 1201B have an inside surface that is configured to hold the lower portion of the respective wireless microphone vertically and substantially concentrically within the respective holster. As can be seen in FIG. 5, the upper edges of the holster surfaces include openings 1222 for cooling air to pass.

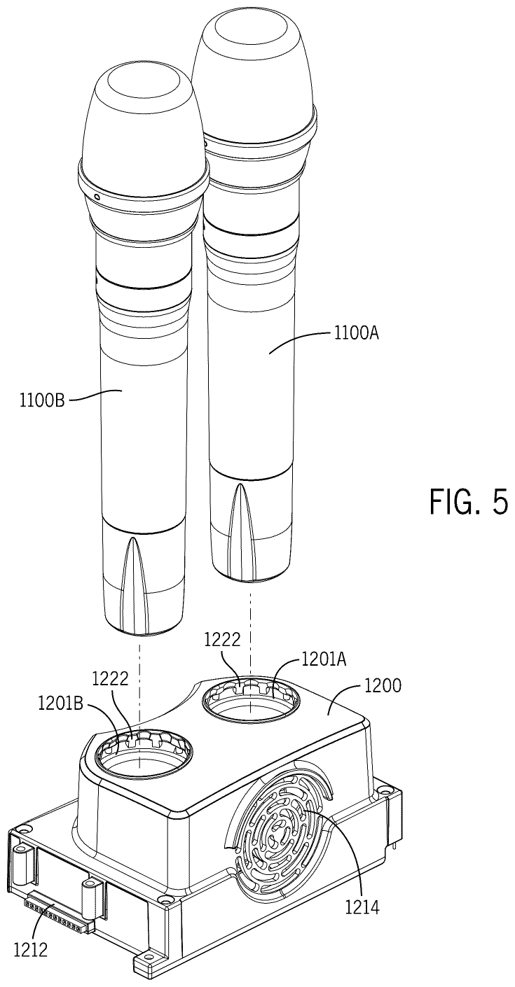

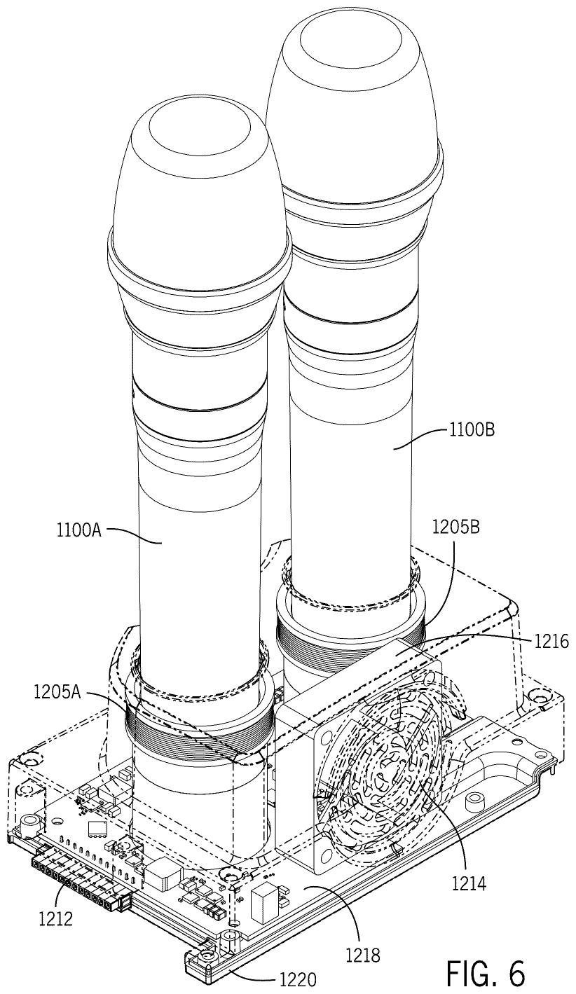

Referring to FIGS. 6 and 7, the cooling fan 1216 and a printed circuit board 1218 are mounted on the base plate 1220 forming the floor of the base portion 1210 of the charging station 1200. The housing shown in dashed lines in FIG. 6 is attached to the base plate 1220. The wireless charging station 1200 has several electronic components mounted to the printed circuit board 1218, including a USB-PD sink controller integrated circuit (IC), a microprocessor and two wireless charging ICs (e.g., transmitter wireless Qi charging controllers). The microprocessor handles communication with the USB-PD sink controller IC, the two wireless charging ICs (e.g., transmitter wireless Qi charging controllers), and any connected charging stations. The USB-PD sink controller IC is an integrated circuit (IC) that manages the power consumption of wireless microphones and is powered by a USB-C cable using the USB Power Delivery (USB-PD) protocol. The microprocessor communicates with the wireless charging ICs (i.e., transmitter wireless Qi charging controllers) to monitor charge status and power draw. The microprocessor requests USB PD power profiles based on its own needs and any charging station connected to it. The microprocessor also monitors the unit temperature and controls the fan speed as needed.

As best shown in FIG. 7, the printed circuit board 1218 includes a male electrical connector 1212 on one side and a female electrical connector 1213 on the other side. The male electrical connector 1212 from one charging station 1200 can be connected electrically into a female electrical connector 1213 on another charging station 1200 in order to electrically connect the charging stations. The USB-PD sink controller IC manages the charge of wireless microphones in the respective charging station. When the wireless microphones 1100A, 1100B are fully charged the power is bypassed to a connected charging station. LED indicators on the charging station show charging status of the charging station itself (power applied, charging mode). Charging status for each of the wireless microphones is preferably provided on the microphone.

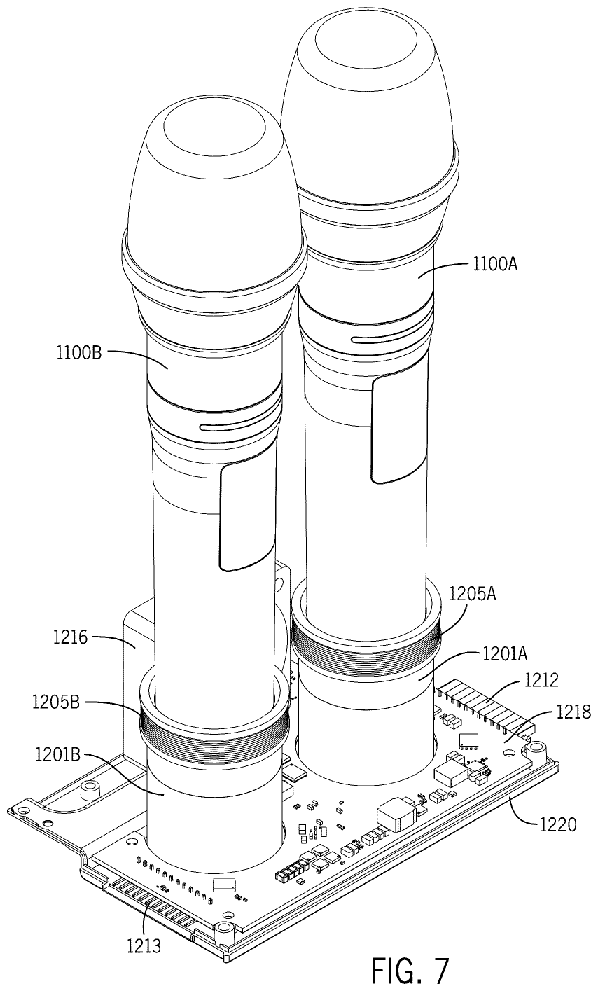

Referring to FIGS. 8 through 11, the cooling fan 1216 draws in ambient air 1224 through the grill 1214 and pushes the cooling air around the charging stand and the charging coils 1205A, 1205B through openings 1222 in the holsters 1201A, 1201B upward around the respective microphone 1110A, 1110B to cool the charging coils 1205A, B and the microphone as needed. As mentioned previously, the microprocessor on the charging station 1200 monitors the temperature and controls the cooling fan 1216 accordingly.

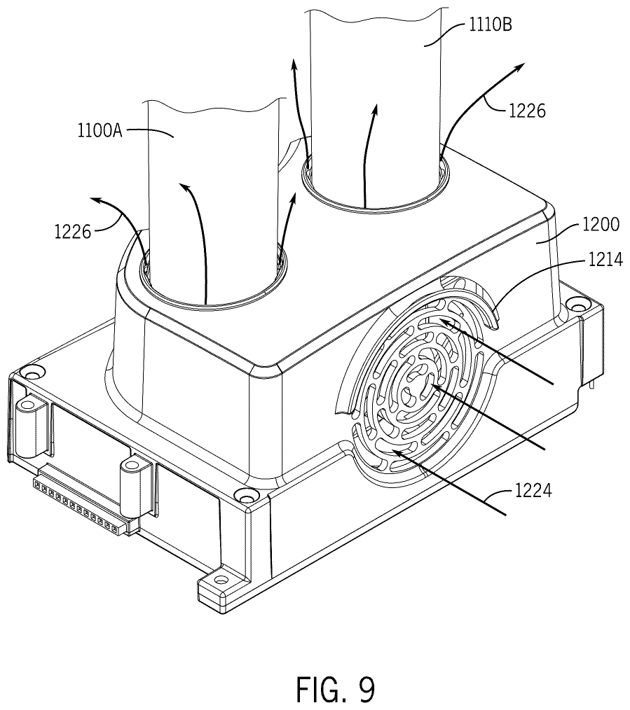

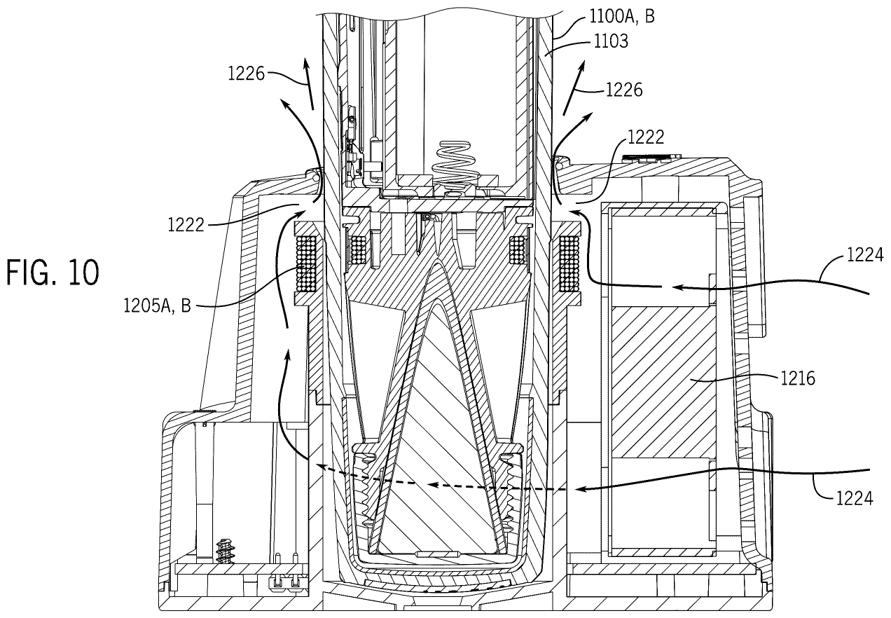

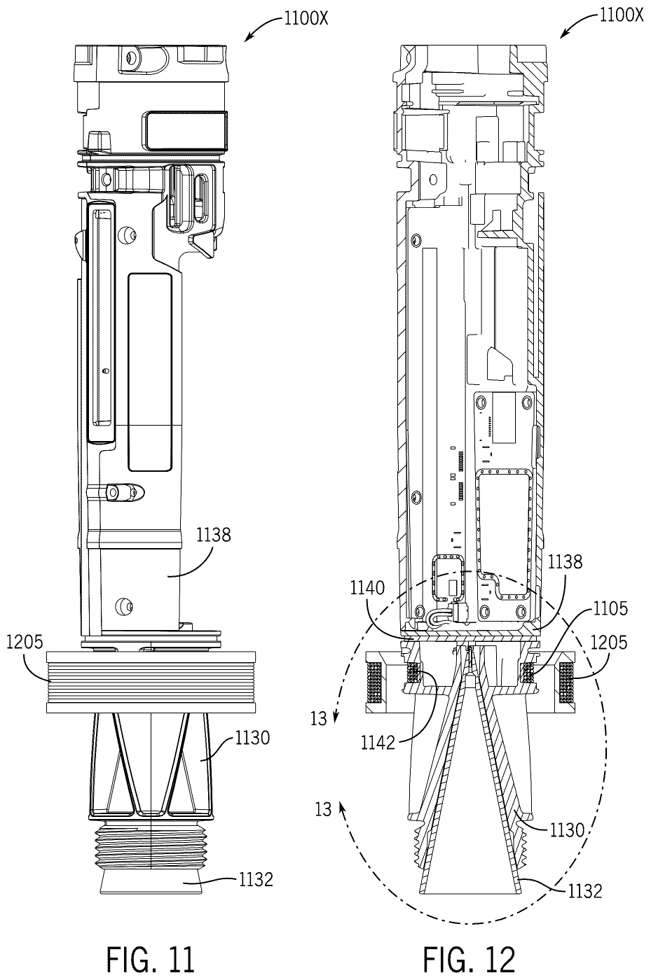

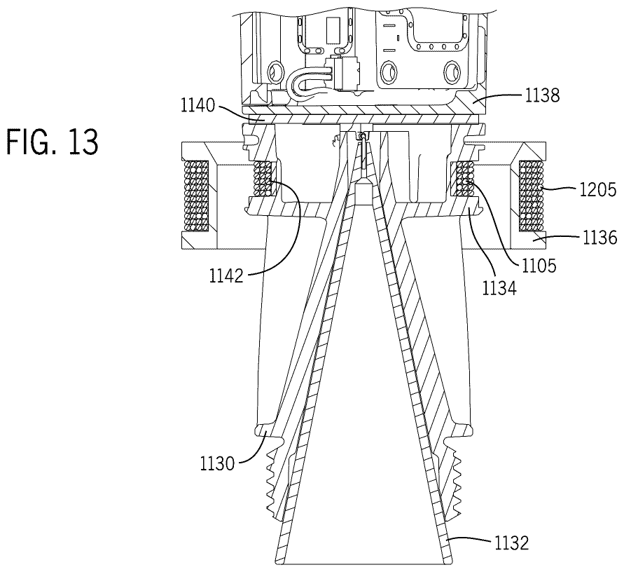

FIGS. 11 and 12 illustrate various internal components of the internal metal frame 1138 and antenna 1132 of the wireless microphone 1100X disclosed in the incorporated U.S. Ser. No. 19/032,311, entitled “Wireless Microphone Dipole RF Antenna,” filed on Jan. 2025 and assigned to the assignee of the present application. FIGS. 11 and 12 also illustrate the relative positioning of the charging coil 1250 on the charging station with respect to the receiving coil 1105 on the microphone 1100X and other illustrated microphone components. FIG. 13 is a detail view of the lower portion of FIG. 12. FIGS. 11 through 13 do not show plastic microphone sleeve 1103 (see FIG. 10) for purposes of illustration. It is important in this embodiment, as well as with other embodiments, that interference of the magnetic field generated by the charging coil 1250 on the charging station by metal structures in the microphone 1100X be minimized, since interference can lead to inefficiency and excess heat generation. In this regard, the relative positioning of the magnetic field generated by the charging coil 1205 with respect to both the receiving coil 1105 on the microphone 1100X and with respect to other metal microphone components is selected to minimize such interference. For example, the position of the receiving coil 1105 is selected to minimize the effect the antenna 1132 and the metal frame 1138 have on the magnetic field generated by the charging coil 1205.

Referring to FIG. 13, the conical metal antenna 1132 is mounted inside the plastic frame 1130. The apex of the metal antenna 1132 is mounted to the metal frame 1138 as described in incorporated U.S. Ser. No. 19/032,311. The receiving coil 1105 is wound around a plastic bobbin 1134 which forms a part of the plastic antenna frame 1130. The plastic bobbin 1134 locates the receiving coil 1105 outward so that it is adjacent to the microphone shell 1103 (not shown in FIG. 13, see FIG. 10) and essentially as close as possible to the charging coil 1205. The charging coil 1205 is wound around a bobbin 1136 on the charging station and is configured such that the magnetic field encompasses the receiving coil 1105 but to minimize interference from the antenna 1132 or other metal components. In addition, in this second embodiment, ferrite plates 1140 and 1142 are used to redirect the magnetic flux through the ferrite plates 1140, 1142 and away from potentially interfering metal components. Non-conductive materials other than ferrite with high magnetic permeability may also be suitable for this purpose. In FIGS. 12 and 13, an annular ferrite plate 1142 is located adjacent to the inside surface of the receiving coil 1105 against the bobbin 1134. The receiving coil 1205 is desirably wound around the annular ferrite plate 1142. A flat ferrite plate 1140 is placed above the receiving coil 1105 and below the main metal frame 1138 in the microphone body, see FIGS. 12 and 13. The flat ferrite plate 1140 next to the metal frame 1138 guides the magnetic flux away from the metal frame 1138. Magnetic flux induced in the metal frame 1138 would create eddy currents that generate heat and may cause the microphone temperature to rise above thermal limits required for battery charging. The flat ferrite plate 1142 also improves the power transfer between the charging coil 1205 and receiving coil 1105. The annular ferrite plate 1142 inside the receiving coil 1105 concentrates magnetic flux around the receiving coil 1105 and improves efficiency of the power transfer between the charging coil 1205 and receiving coil 1105. The size and location of the receiving coil 1205 is configured so it does not interfere with the antenna 1132 and is also positioned far enough away from the metal frame 1138 so that the metal frame does not interfere with the power transfer.

Although this disclosure has included the use of the phrase “exemplary”, the inventors have envisioned alternative designs that are to be considered as within the scope of this disclosure.

1. A wireless microphone charging system comprising a handheld microphone and wireless charging station, wherein the handheld microphone comprises:
an elongated microphone body having a sleeve and a central axis,
a rechargeable battery,
a receiving coil inside the sleeve extending circumferentially around a section of the elongated microphone body; and
wherein the wireless charging station comprises:
a holster with a receptacle for the microphone body and an opening through which the microphone body is set into the receptacle; and
a charging coil in the holster extending annularly around the receptacle, wherein the receptacle is configured to hold the microphone body in a position when fully seated such that the receiving coil on the microphone body resides annularly within the charging coil in the holster, and the receiving coil magnetically couples to the charging coil when charging to transfer power from the charging coil to the receiving coil via induction.

2. The wireless microphone charging system recited in claim 1 wherein:
the charging station further comprises a transmitter Qi wireless charging controller connected to the charging coil; and
the microphone body further comprises a receiver Qi wireless charging controller connected to the receiving coil and to electrical contacts for the rechargeable battery in the microphone body;
wherein power is transmitted from the charging coil to the receiving coil via the magnetic coupling and to the electrical contacts for the rechargeable battery via the receiver Qi wireless charging controller.

3. The wireless microphone charging system recited in claim 1 wherein the charging station further comprises a USB-PD sink controller integrated circuit (IC).

4. The wireless microphone charging system recited in claim 3 wherein the charging station has a male electrical connector and a female electrical connector and the charging station can be connected to one or two additional charging stations using the male or female electrical connector or both the male and female electrical connectors.

5. The wireless microphone charging system recited in claim 1 wherein the wireless microphone further comprises a dipole RF antenna contained within the elongated microphone body, said dipole RF antenna having with a first conductive element and a second conductive element commonly driven in opposing polarity for radiating an electromagnetic waveform capable of carrying information to a receiver, wherein the first conductive element is a cone or a truncated cone, the narrow end of the first conductive element is separated but in close proximity to the second conductive element, and the first conductive element and the second conductive element extend along a longitudinal axis of the elongated microphone body and with a wide end of the cone or truncated cone of the first conductive element disposed near a bottom end of the elongated microphone body, and the second conductive element is a conductive frame for the elongated microphone body, and the receiving coil is positioned below the conductive frame and at a height commensurate with an apex of the antenna.

6. The wireless microphone charging system recited in claim 5 wherein the wireless microphone comprises an annular ferrite plate located adjacent the inside of the receiving coil and a flat ferrite plate located between the receiving coil and the conductive frame.

7. The wireless microphone charging system recited in claim 1 wherein, when the handheld microphone is fully seated in the charging station, the receiving coil is positioned entirely within a cylindrical volume, V_{ch}, enclosed by the charging coil, said cylindrical volume terminating at an upper plane spanned by the uppermost wire loops in the charging coil and a lower plane spanned by the lowermost wire loops in the charging coil, wherein both the upper plane and the lower plane are perpendicular to the central axis.

8. The wireless microphone charging system recited in claim 7 further comprising an annular plate located adjacent to the inside of the receiving coil, said annular plate having high magnetic permeability.

9. The wireless microphone charging system recited in claim 7 further comprising a plate located above the cylindrical volume, said annular plate having high magnetic permeability.

10. The wireless microphone charging system recited in claim 1 wherein the charging station comprises two charging holsters and two charging coils.

11. The wireless microphone charging system recited in claim 1 wherein the charging station further comprises a cooling fan which flows cooling air through the charging station and over the charging coil and through holes in the holster receptacle.

12. The wireless microphone charging system recited in claim 1 wherein the holster receptacle has a cylindrical inside wall, and the microphone sleeve fits in the holster receptacle and is able to be fully seated in the holster receptacle regardless of the rotary angle that the microphone is set in the holster receptacle.
